(19) United States
(12) Patent Application Publication
(10) Pub. No.: US 2006/0036383 A1
(43) Pub. Date: Feb. 16, 2006

(54) Method and device for obtaining a stereoscopic signal

(75) Inventors: Maryline Clare, Pace (FR); Christophe Gisquet, Rennes (FR); Fellx Henry, Rennes (FR)

Correspondence Address: FITZPATRICK CELLA HARPER & SCINTO, 30 ROCKEFELLER PLAZA, NEW YORK, NY, 10112, US

(73) Assignee: CANON RESEARCH CENTRE FRANCE, Cesson-Sevigne (FR)

(21) Appl. No.: 11/179,490

(22) Filed: Jul. 13, 2005

(30) Foreign Application Priority Data
Jul. 13, 2004 (FR) 0407808
Jun. 10, 2005 (FR) 0505944

(51) Int. Cl. G01R 35/00

(52) U.S. Cl. 702/85

(57) ABSTRACT

The invention relates to a method of obtaining a stereoscopic signal from a sequence of monoscopic images. The method firstly comprises a step (S10) of obtaining a sequence of monoscopic images having been captured by an image acquisition apparatus in an acquisition mode enabling several images to be shot in the course of a regular movement substantially tangential to the plane of the lens of the acquisiton apparatus. That step is followed by a step (S31) of forming pairs of images from the sequence of images, each pair being formed on the basis of a predetermined temporal distance then a step of calibrating (S32) the images of the pairs formed, so as to improve the visual correspondence between the two images; Finally, a stereoscopic signal is constructed (S33) from the pairs so calibrated. FIG. 3.

### FIELD OF THE INVENTION

The present invention relates to a method of obtaining a stereoscopic signal from a sequence of monoscopic images.

The present invention applies more particularly to domestic use not requiring an apparatus for acquiring images that has with special functions.

In a complementary manner, the present invention concerns a device adapted to implement such a method.

In order to view images in three dimensions, it is necessary to obtain a pair of particular images which are viewable in stereo by specific apparatuses for stereo viewing. For this, whoever wishes to obtain images viewable in stereo seeks to associate images shot with a different angle of view corresponding to the angle of view that may be had with the right eye and with the left eye. After associating those two images shot with a different angle of view, it is possible to obtain the stereoscopic effect by using for example specific eye glasses the effect of which is to superpose the two images and thus to give the impression of relief to the image.

### BACKGROUND OF THE INVENTION

In the Japanese patent applications JP20020035013 and JP20020035090, a technology is described that is used in digital cameras which assists the user to take shots suitable for obtaining a pair of images which will be viewable in stereo.

This method of assisting the user does not permit a pair of fixed images to be acquired that are destined for viewing in stereo. It does not make it possible to obtain for example a video sequence viewable in stereo Furthermore, that method does not permit any defect in setting or movement of the user and does not make it possible to shoot a continuously moving object since is necessitates an appreciable time of adjustment for the second shooting.

Finally, that method of the state of the art makes it necessary to use a specific acquisition apparatus, provided with that technology.

The present invention aims to mitigate the aforementioned drawbacks by providing a method of obtaining a stereoscopic signal from a sequence of monoscopic images without it being necessary to use a specific acquisition apparatus.

The invention also provides such. a method adapted to obtain pairs of stereoscopic images in an automatic and adaptive manner.

Finally the invention provides for giving the possibility of stereo viewing both of fixed images or of video sequences.

### SUMMARY OF THE INVENTION

To that end, present invention concerns a method of obtaining a stereoscopic signal from a sequence of monoscopic images The method comprises the following steps:
obtaining a sequence of monoscopic images having been captured by an image acquisition apparatus in an acquisition mode enabling several images to be shot in the course of a regular movement substantially tangential to the plane of the lens of the acquisition apparatus;
forming pairs of images from the sequence of images, each pair being formed on the basis of a predetermined temporal distance;
calibrating the images of the pairs formed, so as to improve the visual correspondence between the two images
constructing a stereoscopic signal from the pairs so calibrated.

Thus, it is possible, from a sequence of images obtained beforehand in a homogenous manner with respect to an object, without using a specific apparatus for acquiring images, to construct one or more pairs of images viewable in stereo automatically. The formation of stereoscopic pairs and the construction of the stereoscopic signal may be made adaptively with respect to the sequence of images. Furthermore, the calibration will make it possible for example to obtain better coherency between the two images of the pair in case, at the time of acquiring the sequence of images, the user did not exactly respect regular movement tangentially to the plane of the lens.

According to a preferred embodiment, the predetermined temporal distance depends on the speed of acquiring the images of the sequence of images.

For this, that speed of acquiring the images is preferably deduced by calculating at least one movement vector between the images.

Thus it is possible to adapt the. temporal distance which will determine the stereoscopic pairs on the basis of the sequence. If the sequence was not shot at a constant speed, the temporal distance will be able to adapt as a consequence and the stereoscopic signal will have visual coherency.

Advantageously, the step of forming a pair of images comprises the following steps:
selecting an image of the sequence constituting the first image of the pair;
determining a group of images situated temporally at a distance that is close to the predetermined temporal distance with respect to the first image;
constructing the second image of the pair from images of the group determined.

According to a specific embodiment of the invention, the construction of the second image of the pair is performed by selecting the image situated at a temporal distance that is the closest to the predetermined one.

Thus, the pair of images so constructed will be viewable with a stereo effect.

According to another specific embodiment, the construction of the second image of the pair is performed by interpolating at least a part of the images of the group determined.

Thus, if there are no images in the sequence at a distance precisely equal to the predetermined distance with respect to the first image of the pair, it is possible to construct that image constituting the second image of the pair in order for it to form a suitable stereoscopic pair with the first.

It is possible to perform the calibration by a geometric readjustment such as a vertical readjustment and/or a readjustment of the signal such as a luminance readjustment.

According to an embodiment, the geometric readjustment may be a rotational readjustment.

According to a specific embodiment, the rotational readjustment comprises the following steps:
defining an image part on an image to calibrate of the pair formed;
searching with respect to at least one block of predetermined size of the image part for a rotation with respect to a spatially corresponding block in the other image of the pair;in case the search is positive,
verifying the correspondence of the rotation found with respect to at least one other part of the image to calibrate;

in case of positive verification,
correcting the image to calibrate by performing the opposite rotation to the rotation found.

Thus, the rotational readjustment is accelerated and simplified, in particular by virtue of the use of at least one block in a part of the image, which makes it possible reduce the space for searching for the rotations applied to the image. The method also provides for validating the result of a simplified search with respect to at least one other part of the image, which enables the reliability of the result to be increased.

The rotational readjustment further comprises, prior to the searching step, a step of determining at least one significant block in the defined image part, a block being significant if the value of the variance calculated for the block is greater than a predetermined threshold. Thus, the blocks containing few signal variations which could result in an erroneous readjustment are eliminated.

In case of negative search or negative verification, the block size is decremented and the searching step is performed for that new block size

Such a rotational readjustment method makes it possible to simply and effectively detect and correct rotational offsets for small rotations

According to a preferred embodiment, the step of searching for a rotation of the readjustment method comprises the following steps:
defining several rotation centers and several rotation angles;

for all the rotation centers and for all the rotation angles:
calculating similarity between the current block of the image to calibrate having undergone a rotation about one of the rotation centers and through one of the rotation angles, and the spatially corresponding block of the other image of the pair;
comparing the similarities so calculated, the greatest similarity being that corresponding to the rotation center and the rotation angle of the rotation to be found.

Furthermore, the step of verifying the correspondence of the rotation found comprises the steps of:
calculating similarity between the current block of the image part to calibrate having undergone a rotation about the rotation center and through the rotation angle of the rotation found and the spatially corresponding block of the other image of the pair;
comparing the similarity so calculated with a threshold, the verification being positive when said similarity is greater than said threshold.

Thus, the application of a method of rotational readjustment makes it possible to obtain images of the pair which have a better visual correspondence and which will therefore give a stereoscopic signal of better quality.

According to a preferred embodiment, the construction of a stereoscopic signal is performed by grouping together pairs of images that are formed so as to obtain a stereoscopic sequence of images.

Thus a video sequence viewable in stereo is obtained.

According to another embodiment, the construction of a stereoscopic signal is performed by selecting a pair of images of the pair of images formed, so as to obtain a stereoscopic pair. This selection is made for example using a criterion specific to the signal such as the variance of the histogram or the mathematical correlation between the images of the pair.

Thus, an image that is representative of the sequence of images will be selected in order to be viewable in stereo.

According to a specific embodiment, selecting a pair of images will be performed via a user interface making it possible to vary the angles of view of the images and/or the depth of the images, the user interface making it possible for example to change one of the two images of the pair or each of the two images of the pair by an image earlier or later with respect to the sequence of images captured.

Thus, the user can adapt the images of the pair at will according to the angle of view he prefers and/or the image depth he wishes, by means of a simple and user-friendly interface.

The present invention also concerns a device for the implementation of the method according to the invention. This device comprises:
means for obtaining a sequence of monoscopic images having been captured by an image acquisition apparatus in an acquisition mode enabling several images to be shot in the course of a regular movement substantially tangential to the plane of the lens of the acquisition apparatus,
means for forming pairs of images from the sequence of images, each pair being formed on the basis of a predetermined temporal distance;
means for calibrating the images of the pairs formed, so as to improve the visual correspondence between the two images.
means for constructing a stereoscopic signal from the pairs so calibrated.

This device has the same advantages as the method it implements.

The present invention also concerns an information storage means readable by a computer or a microprocessor storing instructions of a computer program enabling the implementation of a method of obtaining a stereoscopic signal as above.

The present invention also concerns a partially or totally removable information storage means readable by a computer or a microprocessor storing instructions of a computer program, enabling the implementation of a method of obtaining a stereoscopic signal as above.

The present invention also concerns a computer program product able to be loaded into a programmable apparatus, comprising sequences of instructions for implementing a method of obtaining a stereoscopic signal as above, when the program is loaded and executed by the programmable-apparatus.

Still other particularities and advantages of the invention will appear in the following description.

### BRIEF DESCRIPTION OF THE DRAWINGS

In the accompanying drawings, given by way of non-limiting example:
FIG. 1 illustrates a device implementing the invention;
FIG. 2 is a diagram of the positioning of a camera for acquiring a sequence of images to which processing according to the invention can be applied,
FIG. 3 is a block diagram. representing the steps of the processing according to a preferred embodiment;
FIG. 4 is a block diagram describing the step of forming stereoscopic pairs according to one embodiment;
FIG. 5 diagrammatically illustrates the temporal distance used in the embodiment of FIG. 4:
FIG. 6 is a block diagram describing an embodiment of implementation of the calibration according to the invention;
FIG. 7 illustrates the steps of a method of calibration according to the invention with respect to a pair of stereoscopic images;
FIG. 8 illustrates a block diagram describing an embodiment of implementation of rotational calibration according to the invention;
FIG. 9 is a detailed illustration of the step of partitioning the image in the implementation of the rotational calibration;
FIG. 10 and 11 illustrate sub-steps of the rotational calibration applied to an image;
FIG. 12 illustrates the step of a first phase of searching for a rotation in the implementation of the rotational calibration according to the invention;
FIG. 13 illustrates the step of verifying the rotation in the implementation of the rotational calibration according to the invention;
FIG. 14 illustrates the step of selecting the blocks for the implementation of the rotational calibration according to the invention;
FIG. 15 illustrates the steps implemented according to one embodiment of the invention using a user interface;
FIG. 16 illustrates a user interface example for the final selection of the pairs of images according to the invention; and
FIG. 17 is a diagram of a device adapted to implement the invention.

### DETAILED DESCRIPTION

First of all, with reference to FIG. 1, a description will be given of a device 2 for obtaining a stereoscopic signal from a monoscopic sequence of images in accordance with the invention, the sequence being acquired by an image acquisition device. The final stereoscopic signal is viewable by a suitable device.

The acquisition device comprises means 1 for acquiring a monoscopic sequence of images, by using for example a camera in video mode or a digital camcorder. Alternatively, a digital camera may be used in burst mode, i.e. fixed image shooting at the rate of 2 or 3 images per second. The set of images sequentially acquired in this mode may also be considered as a digital video. The signal acquisition must be made by moving the apparatus. As illustrated in FIG. 2 in the example of a digital camera DC, the capture apparatus has three approximate axes of symmetry a horizontal axis 10, a vertical axis 1 1 and a depth axis 12. The axes 10 and 11 define the plane of the shooting lens. The camera DC describes a path 13 through space. It is important that during shooting the speed of movement of the camera does not vary too greatly. The acquisition of the signal must be performed by moving the camera tangentially to the plane defined by the axes 10 and 11, as shown on the diagram of FIG. 2, For example, it is possible to carry out acquisition of the signal by means of “traveling” (translation of the camera in the plane defined by the axes 10 and 11), or else by pointing at the subject whose signal it is desired to acquire while turning around concentrically.

Returning to FIG. 1, the device implementing the method according to the invention comprises processing means 2 making it possible to obtain a stereoscopic signal, in fixed image or video form, on the basis of the video sequence recorded in advance. According to a preferred embodiment of the invention, the processing is performed by a software application, executed on a personal computer or embedded in a printer or image acquisition device for example. The user must either transfer the video to a computer equipped with that software application, or connect the camera to a printer comprising that software application.

The processing device 2 comprises means 21 for forming pairs of images from the sequence, which may be assimilated to images respectively viewed by each eye of the user, optional means 22 for calibrating the images obtained and means 23 for constructing a final stereoscopic signal.

The signal so obtained is viewable by the user by using an appropriate device possessing means for viewing stereoscopic images 3 such as a stereoscope, 3D glasses or display by polarized light.

In a complementary manner, the means for viewing stereoscopic images may be associated with means for user action in the form of a user interface. Thus, the user may modify the pair of images forming the stereoscopic image depending on whether he desires an different angle of view or depth. This will be described later with reference to FIGS. 15 and 16.

A detailed description will now be given of the method of processing a video sequence to obtain a stereoscopic signal with reference to FIG. 3. As input to the algorithm a video V is available, acquired at the prior step S10 according to a method respecting the rules described above with reference to FIG. 2. The first step before processing S30 is the loading of the video onto a device provided with the software application implementing the invention. Such a device will be described in detail with reference to FIG. 8 In the preferred embodiment, the software application is installed on the personal computer of the user. In that case, the loading of the video is performed in a usual manner as for viewing a set of digital photographs/videos on a personal computer In an alternative embodiment, the software application is embedded in an apparatus adapted for viewing the final result of the invention: a printer or video projector adapted to project stereoscopic sequences for example.

The processing starts at step S31 of forming intermediate stereoscopic pairs. In order to a pair of images to be a stereoscopic pair, it is necessary for each of the images of the pair to correspond to what one of the eyes of a user sees. In order to extract such pairs of images from a simple video sequence, the sequence will be gone through a first time to extract a signal corresponding to one eye, for example the left eye, then the initial sequence will be gone through a second time with a temporal offset to generate the second signal corresponding to the right eye in that example. The technical problem to solve is to automatically determine the temporal offset which corresponds to a movement of position for shooting substantially equal to the distance between the eyes of the user. An algorithm giving a solution to this problem in a preferred embodiment will be described with reference to FIG. 4.

Step S31 is followed by a step S32 of calibrating the intermediate stereoscopic pairs obtained. This is because it is sometimes necessary to correct a certain number of shooting defects, such as slight vertical movements of the camera, in order to obtain a stereoscopic sequence with better visual reproduction. The implementation of this step will be detailed with reference to FIG. 6.

After calibration, a stereoscopic signal ready to view is produced at step S33. Depending on the number of images of the initial sequence of images and the wishes of the user, either a stereoscopic video signal or a stereoscopic signal of fixed images can be produced.

If the user wishes to obtain a video stereoscopic signal, a preferred embodiment provides for assembling the left view and the right view of the stereoscopic video side by side, and to save the whole in a conventional format such as the MPEG-2 format so as to facilitate the storage and transport of the video so obtained.

Alternatively, if the user wishes to obtain a pair of fixed images, in the preferred embodiment the selection is made in step S33 of a favored stereoscopic pair from the set of available pairs. For example, the choice of that pair may be left to the user in an interactive manner. An example of interactivity of the user will be described with reference to FIGS. 15 and 16. Alternatively, in the preferred embodiment of the invention, provision is made for the automatic selection of the best stereoscopic pair on the basis of a predetermined criterion, such as the pair whose histogram has the greatest variance, or else the pair which has the greatest correlation between images. The selected pair of fixed images may be stored in a standardized digital format such as JPEG, or printed on paper.

With reference to FIG. 4, a detailed description will now be given of the formation of intermediate stereoscopic pairs according to a preferred embodiment of the invention. Note that in this example, without loss of generality, shooting was performed from left to right, thus the left view of the stereoscopic pair is selected first and then its corresponding right view is determined An opposite method can of course be envisaged.

At the initialization step S41, the first image for the left view is selected, and therefore constitutes the first image of the pair, denoted here by Ll. For example, the first image of the video sequence can be taken.

At the following step S42 the temporal distance or temporal offset d is determined which is linked to the movement of position for shooting between the two eyes. This temporal distance d is a function of the speed of acquisition of the images of the sequence, assuming that this acquisition speed is greater than the speed of movement of the objects filmed. This speed may be practically constant for the duration of shooting, or slightly variable over time. It may thus be envisaged to determine the temporal distance d a single time for the entire sequence, and then to associate it with the set of images processed on the assumption that the speed of acquisition is constant. If information is known about the acquisition speed, it is possible to determine beforehand that d=d0 is constant, in which case step S42 is limited to the reading of that distance d0.

However, in practice it can be assumed that if acquisition of the video is made by the user ‘hand-held’, the speed of acquiring the video is not exactly constant. In the preferred embodiment the speed of acquisition is determined locally with respect to sub-sets of images of the sequence of images, in order to obtain a value of the temporal distance d that is adaptive over time. Preferably, the estimation of the speed of acquisition of the video is made by estimating the movement vector between successive images of the sequence, by using known techniques such as block matching. It is assumed here that the movement is regular over a group of successive images and that the movement of the objects filmed-is slight, i.e. that the movement observed of the objects of the scene is mainly due to the movement of the shooting apparatus.

Thus, the temporal distance d is determined adaptively. The value determined for d may be applied to a set N of successive images of the left view if it is found during the movement estimation that the movement is regular over a group of N images.

Next the step S43 is proceeded to at which a temporal window for image searching is determined, the window being situated around the image located at a distance d from the image of the current selected left view, Llt. For example, the group of images formed from the images situated before and after the image at a distance approximately equal to d from Llt. The group of images so formed, which are all situated at a distance close to the temporal distance d from the first image, is illustrated in FIG. 5.

At step S44 a sub-set of images is selected from within the window W. In the preferred embodiment, this subset is reduced to one image, selected such that the viewing point from which it was shot is spaced from the viewing point of the current left image Llt by a distance substantially equal to the distance between the two eyes. To achieve this, the correlation between the current left image Llt and each of the images of the window W is calculated and selection is made of the one for which the value of correlation obtained is closest to a predetermined correlation value. According to an alternative embodiment, the variance of the difference between the two images is compared to a certain threshold In the case in which all the images of the window W result in values of correlation with the image Llt that are very close, all those images are selected.

At step S45 the right view Rlt corresponding to the left view Llt is finally constructed. If only a single image was chosen at step S44, it becomes the second image of the pair, Rlt. If several images were chosen, an interpolation of the images selected is carried out in order to obtain that second image of the pair Rlt. In the preferred embodiment, this interpolation consists of generating an image of which each pixel has the average value of the pixels of the same spatial position in each of the images chosen.

Other alternative embodiments may be envisaged. For example, if the estimated temporal distance d does not have an integer value, an interpolation may be made between the images of the window W in order to obtain an estimated representation of the image shot at a distance precisely equal to d from the image Llt. This image will then be chosen as the second image of the stereoscopic pair, Rlt.

Once the stereoscopic pair has been obtained, it is sent to the calibration module, detailed below at FIG. 6.

The algorithm continues with the test at step S47 for verifying whether the group of images belonging to the temporal window W contains the last image of the sequence. If this is the case, the processing ends. Otherwise, the following image of the sequence is selected as current image of the left view Llt and steps S42 to S47 are again performed.

The calibration of a stereoscopic pair of images will now be described with reference to FIGS. 6 to 14. More particularly, as explained earlier, two views are available corresponding to a left view Ll and a right view Rl, represented in FIG. 7. The correspondence of these images may be imperfect since they are extracted from a sequence of images which may have been shot ‘hand-held’, without any specific positioning mechanism of the shooting apparatus.

Several corrections are possible in this calibration step. In the preferred embodiment, three types of correction are described, a geometric correction concerning the vertical offset, a correction of the signal by compensation for the luminance and a correction of a rotational offset. These corrections may be implemented independently.

The steps of an example of a calibration algorithm are described with reference to FIG. 6.

Firstly, at step S61 a vertical offset is determined between the first image IG and the second image ID of a pair constructed previously. For this, a predetermined search interval is considered, for example from −10 to +10 pixels. For each value p pixels of that interval, the vertical offset of one of the images is performed, for example of the image Rl, by p pixels and the correlation is calculated between the offset image and the original image of the other view. The vertical offset chosen is that which maximizes the correlation value.

Next at step S62 the offset determined at the prior step is applied to the view concerned, for example the right view. In the preferred embodiment, the missing pixels are replaced by black pixels. A new right view Rl′ is then obtained, illustrated in FIG. 7.

At the following step S63 luminance compensation is performed with respect to the pair of images Ll and Rl′. Luminance compensation is a technique known to the person skilled in the art, also known as histogram equalization. It consists of calculating the histogram of the image Ll, and then of modifying the levels of luminance of the image Rl′ such that its histogram is the closest possible to that of the image Ll in terms of a mathematical distance. An image Rl* is thus obtained, also represented in FIG. 7.

The stereoscopic pair finally obtained (LO, Rl*) is the final stereoscopic pair after calibration.

With reference to FIG. 8 to 14, a description will now be given of an example embodiment of a simple method of rotational adjustment. It is assumed here that the rotation experienced between the two images of the pair is slight.

FIG. 8 illustrates the different steps of the implementation of the rotational readjustment or calibration. The object of step S81, detailed in FIG. 9, is to initialize and to define useful values for the remainder of the process; block size, number of rotation angles and centers to test, division of the image into image parts to which the rotation will be applied.

Step S82, detailed in FIG. 12, searches whether a rotation may be identified in a first part of the image. The image to consider here, being one of the images of the pair, the one for which calibration will be made, the rotation being determined with respect to the other image of the pair.

The test of step S83 makes it possible guide what follows in the process depending on the result of step S82. If a rotation has been identified, it is sought at step S84 whether the image has other parts for which it must be verified whether the rotation is also identified. If that is the case, step S85 defines the next part of the image as the “current part”, and step S86 (detailed in FIG. 13) verifies that the rotation identified for the first part is also identifiable for the current part. Step S87 returns the process to step S84 should the same rotation have been identified for the current part. On the other hand, if that rotation is not confirmed, it is verified at step S89 that the size of the blocks being worked with is not the minimum size determined at step S81. If it is the minimum size, the process is exited via step S90 which gives the result that no global rotation has been identified for the image.

If the result of step S89 indicates that the search has not been performed with respect to all the possible block sizes, the block size is updated (step S91) by decrementing the current step value defined at step S81. The process then resumes at step S82, i-e with the search for a rotation of the first part of the image, by considering this time only blocks of the size that has just been updated.

If the result of step S83 indicates that no rotation has been found in first part, step S89 is proceeded to directly.

Finally, if at the end of step S84 it is found that all the image parts [symbol] e been verified, this means that for the current size of block, step S87 has [symbol] ays indicated that the rotation considered had been verified with respect to [symbol] the parts of the image. In conclusion, it is then possible to proceed to step [symbol] 8 having decided that the rotation considered since the end of step S82 is a [symbol] bal rotation of the image.

FIG. 9 details step S81 of FIG. 8, i.e. the initializations and [symbol] finitions of values useful to the overall process. First of all, step S92 defines [symbol] number of parts with respect to which the rotation will be verified. In the [symbol] ample of step S92, four parts are defined, which means that a rotation will be [symbol] arched for with respect to the first part and that, where applicable, it will then [symbol] verified with respect to the three remaining parts. In the preferred [symbol] bodiment, the four parts are obtained by cutting up the image into four [symbol] ocks of equal size.

Step S93 defines a number of angles to test. In this example [symbol] bodiment, only small positive or negative angles are tested. These values [symbol] pend on the type of application, or even on the type of photographs to be [symbol] ocessed. It is easy be imagine the system being “self-parameterizing” in order [symbol] efine the search, and for example that it would restart the process for new [symbol] ngles (intermediate or greater than those defined) in case no rotation had [symbol] een found.

Step S94 defines rotation centers which are then tested with each [symbol] ngle defined at step S93, so defining the parameters of the rotations sought in [symbol] e image. Here too, it will be important to be able to refine the number of those [symbol] tation centers in order in all cases to be able to identify the rotation if it exists.

FIG. 10 illustrates the definition of 9 rotation centers as given in [symbol] e example of step S94.

Step S95 manages everything that relates to the block sizes. More [symbol] articularly, a maximum block size is started with in order to see if a rotation [symbol] an already be detected in relation to large blocks. If not, the search will be [symbol] ommenced with respect to smaller blocks. In the example given at step S95, [symbol] maximum block size is defined as being 1/8th of the width of the image, and [symbol] minimum size as being 4×4 pixels. Passage from one size to the other is [symbol] de by decrementing by a value of 2 pixels. The successive blocks overlap as [symbol] strated in FIG. 11.

Step S96 defines the values of thresholds which enable it to be [symbol] cided whether a block is significant or not, and whether a similarity is proved [symbol] not. It goes without saying that these values are determined empirically and [symbol] pend directly on the measurements used to decide on the relevance of a [symbol] ock (for example the variance of the block) and on the similarity of two blocks [symbol] r example absolute error). If, for the relevance of a block, it is decided to [symbol] lculate several directional variances for each block (the sum of the squares of [symbol] e pixel differences in 4 directions— horizontal, vertical and 2 diagonal [symbol] rections), the value must be adapted, or even represented by 4 values.

FIG. 12 describes step S82 of FIG. 8 more precisely, i.e. the [symbol] arch for the rotation with respect to the first part of the image. This step make [symbol] possible to test all the rotation parameters with respect to all the blocks [symbol] termined as significant as meant by the description of FIG. 14, and to [symbol] lect the couple (rotation angle, rotation center) which gave an optimum result [symbol] th respect to a block judged to be relevant by the relevance threshold.

Step S121 (detailed in FIG. 14) determines whether any significant [symbol] ocks remain in the first part of the image. If so, it selects the next one (step [symbol] 122), and then enters a double loop: to be precise, each couple of parameters [symbol] tation age α, rotation center C) as defined at step S81 of FIG. 8 is tested [symbol] the significant block selected. For this the coordinates of the spatially [symbol] rresponding block in the target image are calculated (step S123), i.e. of the [symbol] ock which in the target image which would correspond to the current source [symbol] ock after a rotation of parameters (α,C) These coordinates are calculated on [symbol] e basis of conventional formulae known in the case of planar rotations. Note [symbol] re that since a rotation is considered, the block spatially corresponding to the [symbol] urce block will be displaced and deformed (placed at an angle α with respect [symbol] the frame of reference of the image). It is thus necessary to have at least one [symbol] the coordinates of two comers of that block in order to define it.

If some of these coordinates are outside the image, it is possible to [symbol] oceed in several manners:

the pair (α,C) is abandoned and the next one is then proceeded to;

comparison is restricted to the included block which does not “go [symbol] tside” the image after rotation;

the “out of image” values are set to dummy values such as those [symbol] ntained at the boundary of the image.

Next a target block is formed of the same size as the source block by [symbol] plying, if necessary, an interpolation to the pixels of the block spatially [symbol] rresponding to the target image, in order to facilitate the later comparison [symbol] ith the source block. For the cases in which the rotation angle tested is very [symbol] all (less than 10 degrees for example), the rotation may be assimilated to a [symbol] mple translation, and forming the target block consists of a simple copying [symbol] peration without requiring interpolation.

At step S124, determination is made of the similarity between the [symbol] urce block and the target block so obtained. Here too, conventional [symbol] easurements are used: the absolute error between the source block and the [symbol] rget block, the difference between the variances, etc.

Next, it is tested whether that similarity is significant by virtue of step [symbol] 125 which compares it to a threshold predefined at step S81 of FIG. 8. If [symbol] at is not the case, the next couple (α,C) is proceeded to. On the other hand, if [symbol] e similarity calculated is significant, step S126 is reached at which it is then [symbol] mpared to the maximum similarity obtained during the preceding evaluations. [symbol] the current similarity is less great, in that case too the following couple (α,C) [symbol] proceeded to. Otherwise it is considered that the couple (α,C) is a candidate [symbol] r the rotation found and the maximum value of similarity is thus replaced by [symbol] e newly calculated value of similarity, and the couple (α,C) is stored (step [symbol] 127). The following couple (α,C) is then proceeded to.

When all the couples (α,C) have been tested on the current source [symbol] lock, step S121 is returned to.

When all the significant blocks have been tested, step S128 is proceeded to which verifies whether a rotation has been detected, i.e. whether at least one couple (α,C) has been stored; if that is the case, the procedure is exited (step S130) delivering the couple that corresponded to the maximum similarity for all the significant blocks, so specifying that the couple (α,C) defines the rotation observed on the current part of the image. Otherwise the procedure is exited stating that no rotation was found for that part of the image (step S129).

FIG. 13 describes more precisely step S86 of FIG. 8, i.e. the verification that a rotation with parameters (α,C) applies to a given part of the image. This procedure resembles that described in FIG. 12, except that it does not test all the possible couples (α,C) since it only considers one, that which was judged optimal at the end of the search with respect to the first part. Furthermore, the similarity is considered significant when it is greater than the threshold given at step S96. On the other hand, there is no longer any need to compare it to a maximum since storing a pair (α,C) is not concerned here.

Step S131, identical to step S121, determines whether there remain any significant blocks in the current part of the image. If that is the case, the next block is selected (step S132, identical to step S122), then the coordinates of the target block, i.e. the block which in the target image would correspond to the current source block after a rotation with parameters (α,C), are calculated (step S133, identical to step S123). These coordinates are calculated on the basis of conventional formulae known in the case of planar rotations:

The test of step S134 makes it possible to verify whether the target block is entirely included within the boundaries of the image. If this is not the case, step S131 is returned to.

If it is indeed within the image, step S135 is proceeded to which measures, as for step 5124 of FIG. 12, the similarity between the target block obtained and the source block.

Step S136 compares that level of similarity with a predefined threshold at step S96. If the similarity measured is less than that threshold, step S131 is returned to. Otherwise the procedure can be exited immediately stating that the rotation tested is verified with respect to that image part (S138).

If at step S131, there remain no significant blocks in the given image part, the rotation (α,C) is not confirmed with respect to that image part (S137).

FIG. 14 describes step S121 of FIG. 12 more precisely (and thus also step S131 of FIG. 13). First of all the test of step S141 verifies that all the blocks of the current size t in the image have not been gone through. If all the blocks have been gone through, exit is made via step S145, thus indicating that no more significant blocks remain.

Otherwise, the next block of size t is extracted at step S142 that is to say as FIG. 11 shows, by taking the next block with a horizontal offset of the step value defined at step S95. If the end of the image is reached horizontally, offsetting is made with the same step value, but this time downwardly and by positioning to the extreme left. Step S143 next evaluates whether the block is significant or not, for example here by calculating the variance or variances of the block. In the case of several measurements, directional variances are concerned (sums of the squares of the pixel differences in 4 directions —horizontal, vertical and 2 diagonal directions), making it possible to determine a more significant activity than that detected by the cancellation of the variance alone. If these variances are greater than the thresholds defined at step S96, the block is declared significant (step S144), and the procedure is exited. Otherwise step S141 is again proceeded to.

Thus, after having found. the right couple (α,C) in relation to the rotation between two images of the pair, the calibration is made by performing the rotation found with respect to one image, by known techniques, for example interpolation techniques. Thus, the images of the pair are calibrated and may thus constitute a pair of images forming a stereoscopic image.

With respect to FIG. 15, a description will now be given of the method of stereoscopic image obtainment in the case where the user can participate in the choice of a pair of images. Thus, at step S151, the selection of two images is made in accordance with the method described in FIG. 4. At step S152, a processing or calibration is performed on the two selected images using one of the methods described in FIGS. 6 to 14, or several of them. At step S153, the two images so calibrated are displayed to the user in order for him to be able to verify the viewing comfort of the stereoscopic image resulting therefrom.

The test of step S154 determines whether the user is satisfied with the three-dimensional vision obtained. For this it is for example proposed to him to use the “Enter” key on the keyboard to confirm that he is satisfied. If that is not the case, step S155 is proceeded to at which he may use the keys of the keyboard to modify that view, as detailed in FIG. 16. When both images are updated, step S152 is returned to.

If the test of step S154 is positive, that is to say when the user is satisfied with the stereoscopic result obtained and has indicated this by pressing as proposed here on the “Enter” key, th process is terminated.

FIG. 16 details the step S155 of FIG. 15. The user wishing to modify the visual appearance of the stereoscopic image obtained by the pair of images displayed at step S153 can adjust the angle of view of the scene and the depth of the image. Several possible actions listed here from A1 to A5 are proposed to him depending whether he presses the keys T1 to T5 respectively.

Thus, the angle of view is adjusted by using the right and left arrows of a keyboard. The right arrow shifts each of the two views of an image, by taking the following pair in the sequence; the left arrow takes the preceding pair in the sequence.

The depth is adjusted using the up and down arrows of the keyboard, The up arrow changes the right image by replacing it with the following image in the sequence, whereas the left image remains the same. As regards the down arrow, this returns the right image to a preceding image in the sequence while also leaving the left image unchanged. The sensation of depth is different since the images have greater separation between them in the original sequence. This separation between the images may be achieved in many other ways, for example by proposing to shift the left image as well, or even by offering a “non integer” offset, i.e. that the offset image proposed would in fact be the interpolation of two successive images.

Other interactions with the user may be envisaged: for example, the operation could be cancelled at any time by means of the “Escape” key. Similarly, there could be provided a “Reset” to return to the initial choice.

Interventions by the user on the computer keyboard have been indicated here. Of course, use of the mouse or a touch screen for example could also be envisaged.

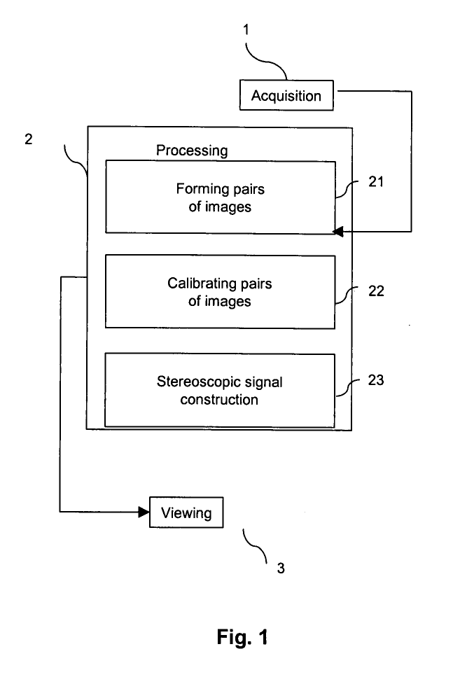

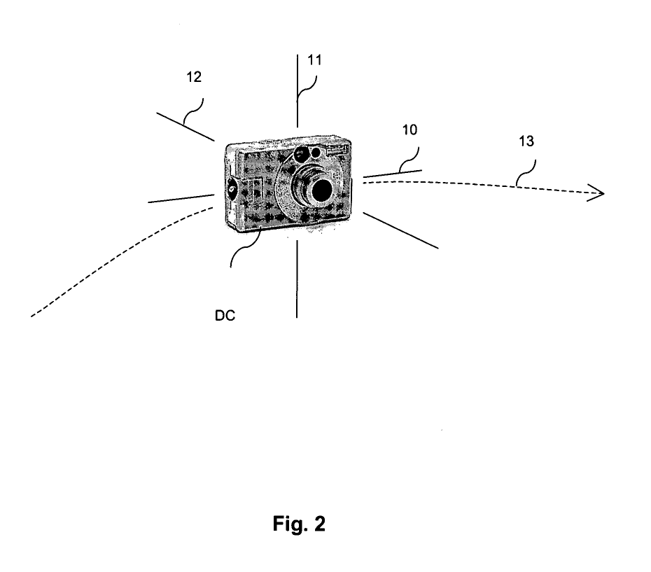

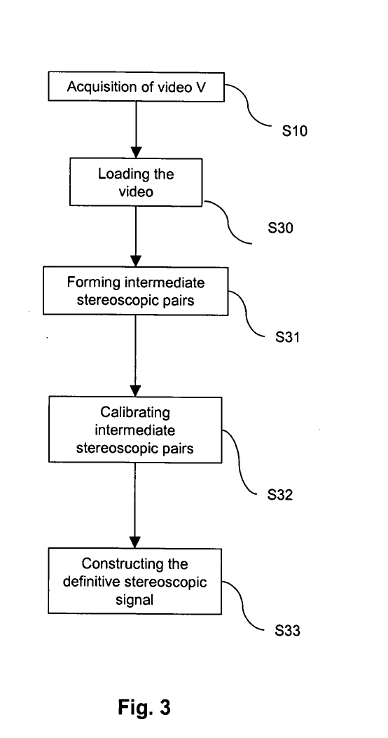

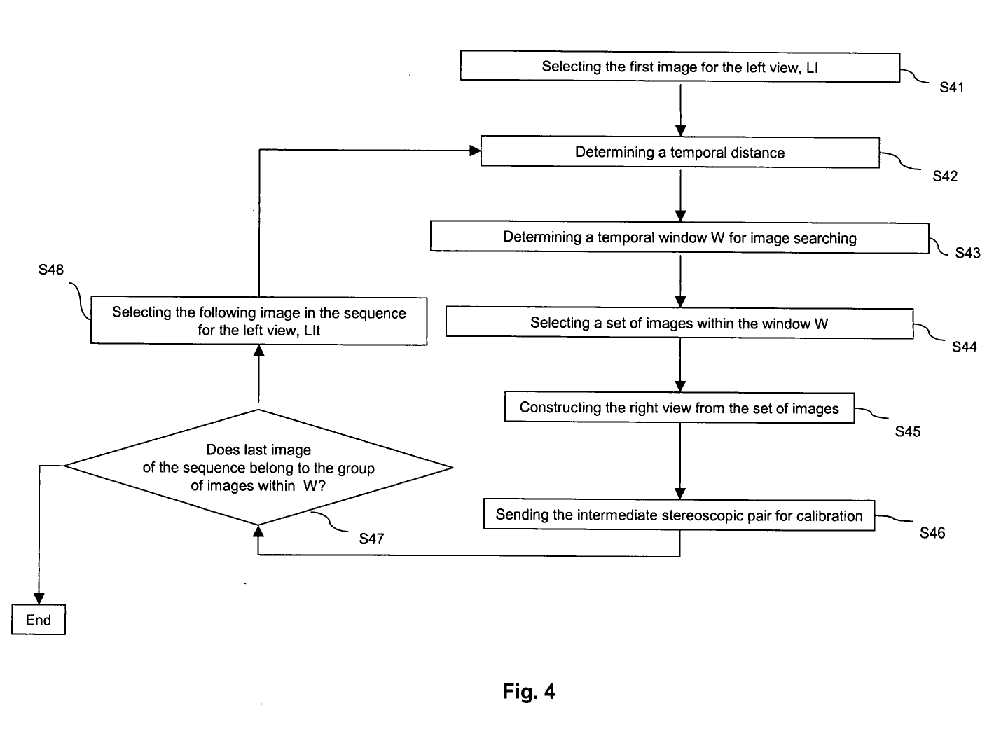

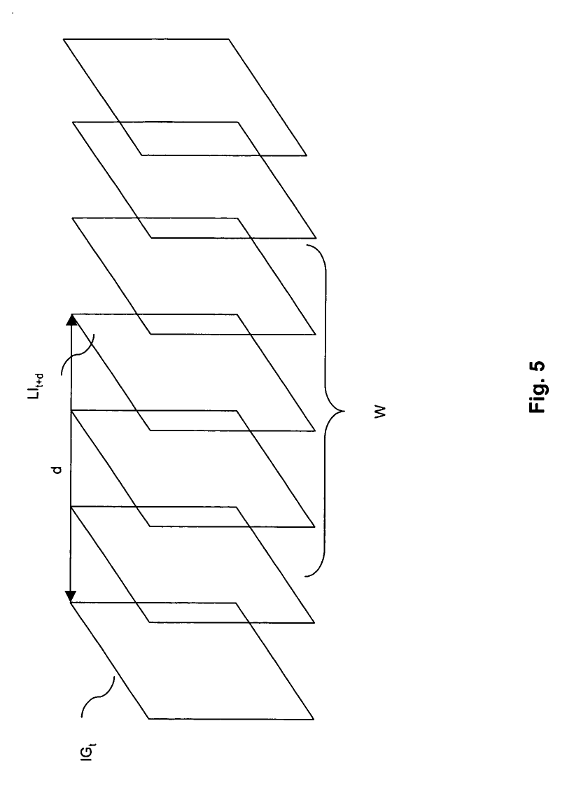

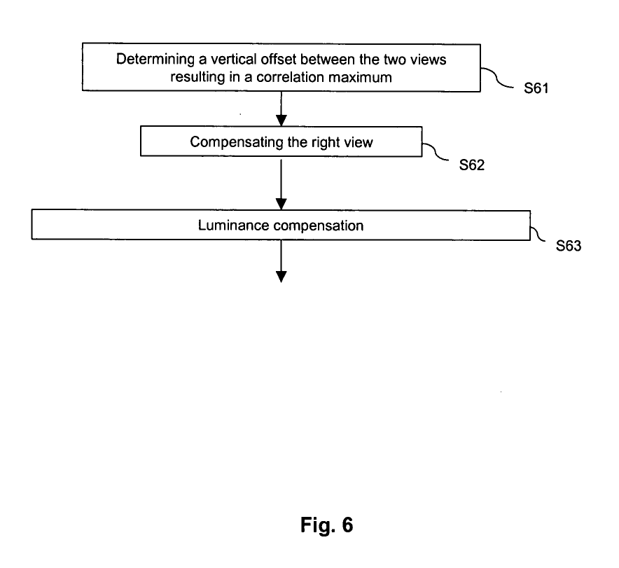

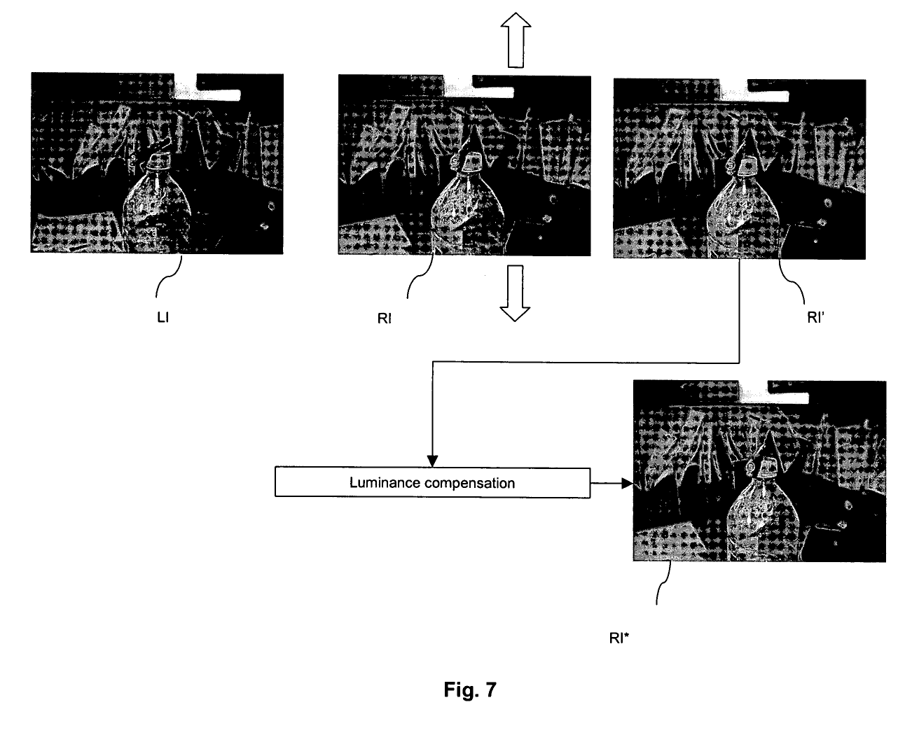

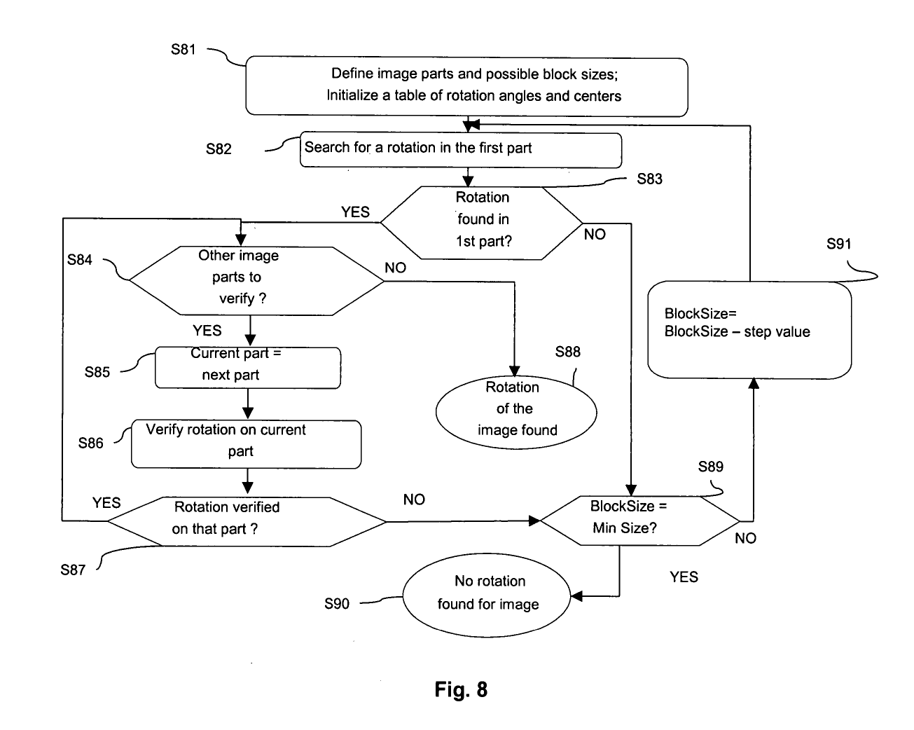

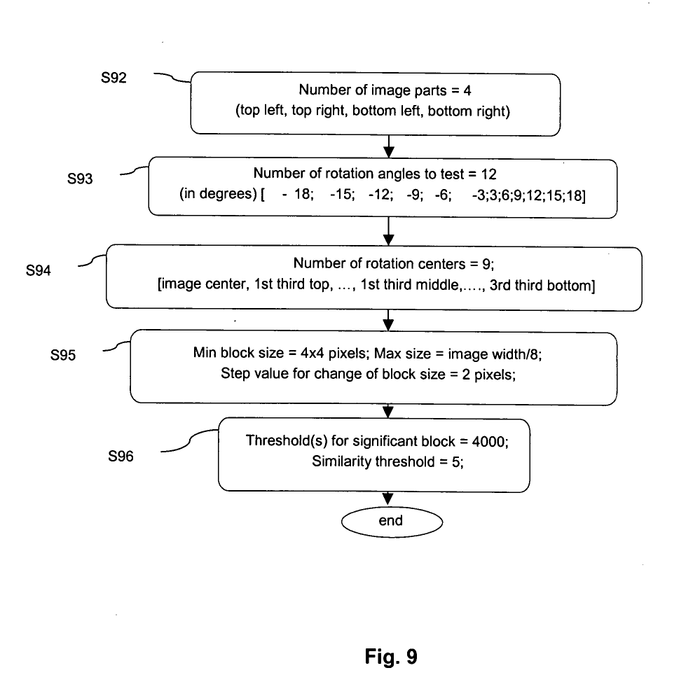

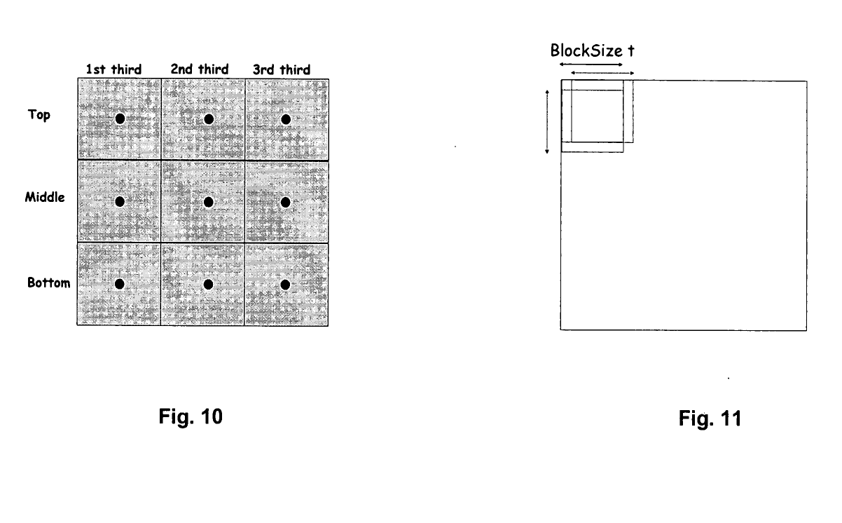

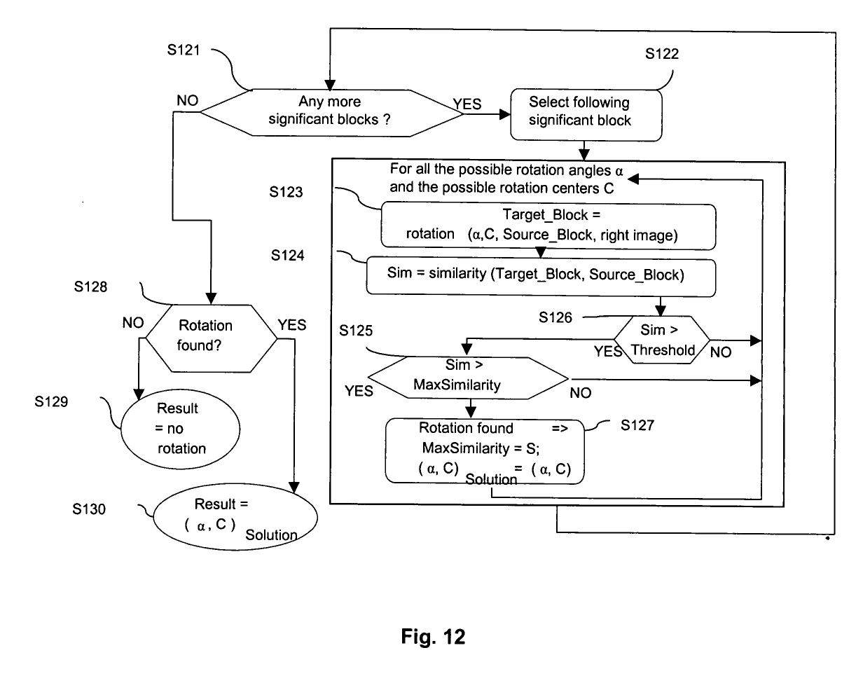

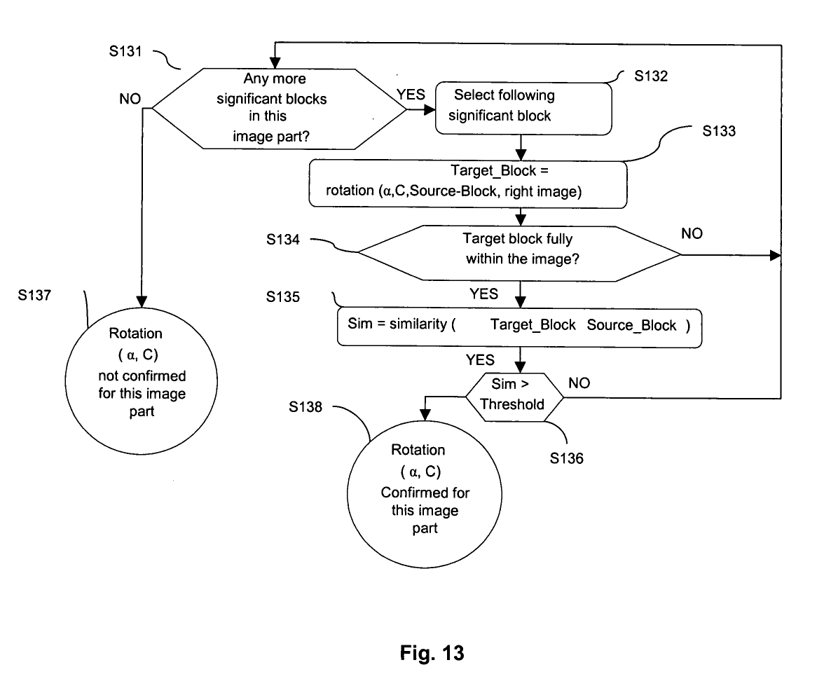

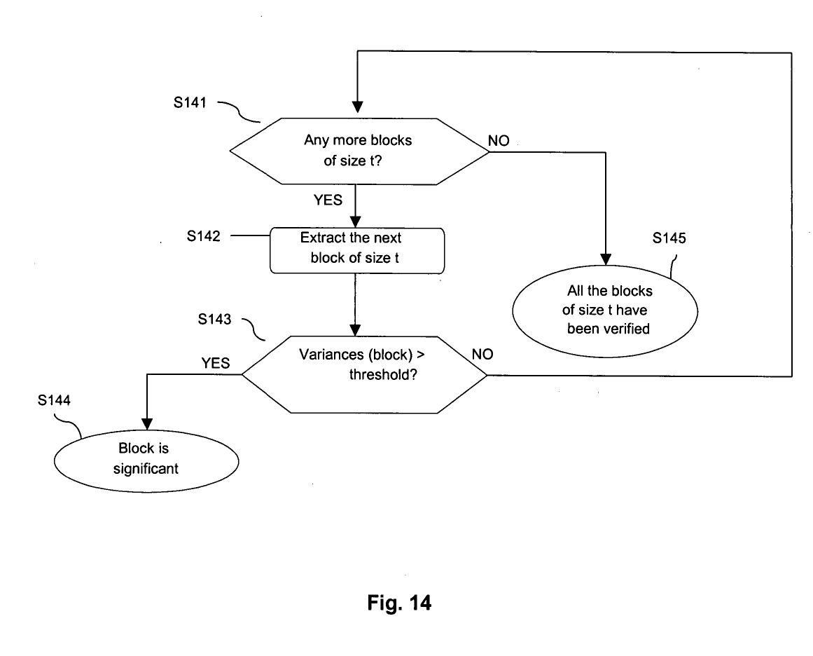

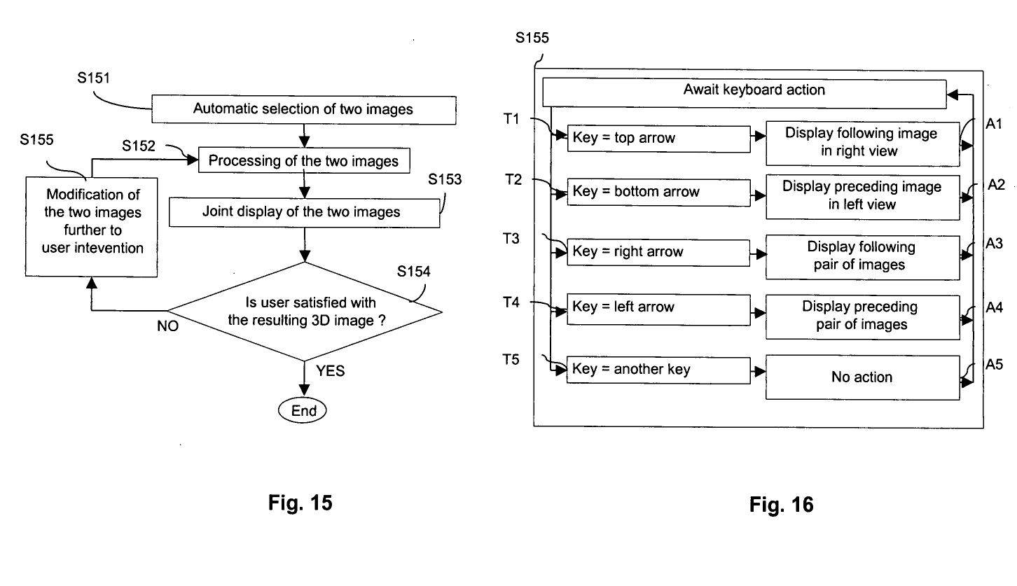

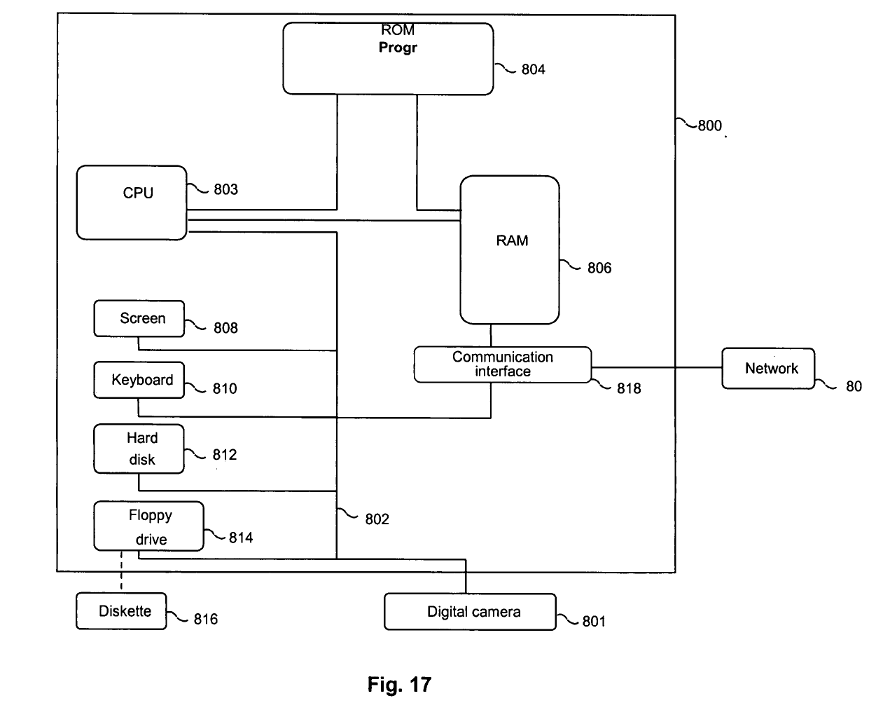

A description will now be given with reference to FIG. 17 of a diagram of a device adapted to implement the method according to the invention.

Such an apparatus is for example a micro-computer 800 connected to different peripherals, for example a digital moving picture 801 connected to a graphics card. The apparatus may also be connected via a specific port to an image acquisition apparatus such as a digital camera in order to receive a data stream to process according to the invention, such as a sequence of digital images.

The apparatus may also be a printer or another peripheral adapted to implement the invention.

The device 800 comprises a communication interface 818 connected to the communication network 80 adapted to transmit digital data processed by the device for possibly sending them to a remote machine for viewing/printing. The device 800 also comprises a storage means 812 such as a hard disk. It also comprises a drive 814 for a disk 816. This disk 816 may be a diskette, a CD-ROM, or a DVD-ROM, for example. The disk 816, like the disk 812, can contain data processed according to the invention, such as an initial sequence of digital images, as well as the. program or programs implementing the invention which, once read by the device 800, will be stored on the hard disk 812. According to a variant, the program Progr enabling the device to implement the invention can be stored in read only memory 804 (referred to as ROM in the drawing). In a second variant, the program can be received in order to be stored in an identical manner to that described previously via the communication network 80. This same device has a screen 808 making it possible in particular to view the data to be processed and serving as an interface with the user who can thus parameterize certain processing modes, using the keyboard 810 or any other pointing means, such as a mouse, an optical stylus or a touch screen.

The central processing unit 803 (referred to as CPU in the drawing) executes the instructions relating to the implementation of the invention, which are stored in the read only memory 804 or in the other storage means. On powering up, the processing programs stored in a non-volatile memory, for example the ROM 804, are transferred into the random access memory RAM 806, which will then contain the executable code of the invention, as well as registers for storing the variables necessary for implementing the invention.

In more general terms, an information storage means, which can be read by a computer or microprocessor, integrated or not into the device, and which may possibly be removable, stores a program implementing the method according to the invention.

The communication bus 802 affords communication between the different elements included in the microcomputer 800 or connected to it. The representation of the bus 802 is not limiting and, in particular, the central processing unit 803 is able to communicate instructions to any component of the microcomputer 800 directly or by means of another element of the microcomputer 800.

1. A method of obtaining a stereoscopic signal from a sequence of monoscopic images comprising the following steps:
obtaining (S10) a sequence of monoscopic images having been captured by an image acquisition apparatus in an acquisition mode enabling several images to be shot in the course of a regular movement substantially tangential to the plane of the lens of the acquisition apparatus.
forming (S31) pairs of images from the sequence of images, each pair being formed on the basis of a predetermined temporal distance;
calibrating (S32) the images of the pairs formed, so as to improve the visual correspondence between the two images;
constructing (S33) a stereoscopic signal from the pairs so calibrated.

2. A method of obtaining a stereoscopic signal according to claim 1, wherein the predetermined temporal distance depends on the speed of acquisition of the images of the sequence of images.

3. A method of obtaining a stereoscopic signal according to claim 2, wherein the speed of acquisition of the images is deduced by the calculation of at least one movement vector between the images.

4. A method of obtaining a stereoscopic signal according to claim 1, wherein the step of forming a pair of images comprises the following sub-steps:
selecting (S41) an image of the sequence constituting the first image of the pair;
determining (S43) a group of images situated temporally at a distance that is close to the predetermined temporal distance with respect to the first image;
constructing (S44, S45) the second image of the pair from images of the group determined.

5. A method of obtaining a stereoscopic signal according to claim 4, wherein constructing the second image of the pair is performed by selecting the image situated at a temporal distance that is the closest to the predetermined distance.

6. A method of obtaining a stereoscopic signal according to claim 4, wherein constructing the second image of the pair is performed by interpolating at least a part of the images of the group determined (S45).

7. A method of obtaining a stereoscopic signal according to claim 1, wherein the calibrating step is performed by geometric readjustment (S61).

8. A method of obtaining a stereoscopic signal according to claim 1, wherein the calibrating step is performed by a readjustment of the signal (S63).

9. A method of obtaining a stereoscopic signal according to claim 8, wherein the readjustment of the signal is a luminance readjustment.

10. A method of obtaining a stereoscopic signal according to claim 7, wherein the geometric readjustment is a vertical readjustment.

11. A method of obtaining a stereoscopic signal according to claim 7, wherein the geometric readjustment is a rotational readjustment.

12. A method according to claim 11, wherein the rotational readjustment comprises the following steps:
defining an image part on an image to calibrate of the pair formed;
searching with respect to at least one block of predetermined size of the image part for a rotation with respect to a spatially corresponding block in the other image of the pair;
in case the search is positive,
verifying the correspondence of the rotation found with respect to at least one other part of the image to calibrate;
in case of positive verification,
correcting the image .to calibrate by performing the opposite rotation to the rotation found.

13. A method according to claim 12, wherein prior to the searching step it comprises a step of determining at least one significant block in the defined image part.

14. A method according to claim 13, wherein the block is significant if the value of the variance calculated with respect to the block is greater than a predetermined threshold.

15. A method according to claim 12, wherein in case of negative search or negative verification, the block size is decremented and the searching step is performed for that new block size.

16. A method according to claim 12, wherein the step of searching for a rotation comprises the following steps:
defining several rotation centers and several rotation angles;
for all the rotation centers and for all the rotation angles:
calculating similarity between the current block of the image to calibrate having undergone a rotation about one of the rotation centers and through one of the rotation angles, and the spatially corresponding block of the other image of the pair;
comparing the similarities so calculated, the greatest similarity being that corresponding to the rotation center and the rotation angle of the rotation to be found.

17. A method according to claim 16, wherein the step of verifying the correspondence of the rotation found comprises the steps of:
calculating similarity between the current block of the image part to calibrate having undergone a rotation about the rotation center and through the rotation angle of the rotation found and the spatially corresponding block of the other image of the pair;
comparing the similarity so calculated with a threshold, the verification being positive when said similarity is greater than said threshold.

18. A method of obtaining a stereoscopic signal according to claim 1, wherein constructing a stereoscopic signal is performed by grouping together (S33) the pairs of images formed so as to obtain a sequence of stereoscopic images.

19. A method of obtaining a stereoscopic signal according to claim 1, wherein constructing a stereoscopic signal is performed by selecting (S33) a pair of images from the pairs of images formed, so as to obtain a stereoscopic image.

20. A method of obtaining a stereoscopic signal according to claim 19, wherein selecting a pair is performed according to a criterion specific to the signal such as the variance of the histogram or the mathematical correlation between the images of the pair.

21. A method according to claim 19, wherein selecting a pair of images is performed via a user interface making it possible to vary the angles of view of the images and/or the depth of the images.

22. A method according to claim 21, wherein selecting a pair of images by the user interface is followed by the step of calibrating the images of the selected pair then displaying the stereoscopic image constructed from the calibrated images, the steps of selecting, calibrating and displaying being performed iteratively until validation is performed by the user.

23. A method according to claim 21, wherein the user interface makes it possible to change one of the two images of the pair or each of the two images of the pair by an image that is earlier or later with respect to the sequence of images captured.

24. A device for obtaining a stereoscopic signal from a sequence of monoscopic images comprising:
means (1) for obtaining a sequence of monoscopic images having been captured by an image acquisition apparatus in an acquisition mode enabling several images to be shot in the course of a regular movement substantially tangential to the plane of the lens of the acquisition apparatus.
means (21) for forming pairs of images from the sequence of images, each pair being formed in the basis of a predetermined temporal distance;
means (S32) for calibrating the images of the pairs formed, so as to improve the visual correspondence between the two images;
means (23) for constructing a stereoscopic signal from the pairs so calibrated.

25. A device according to claim 24, wherein the predetermined temporal distance depends on the speed of acquisition of the images of the sequence of images.

26. A device according to claim 25, further comprising means for calculating at least one movement vector between the images so as to deduce the speed of acquisition of the images.

27. A device according to claim 24, wherein the means for forming a pair of images comprise:
means for selecting an image of the sequence constituting the first image of the pair;
means for determining a group of images situated temporally at a distance that is close to the predetermined temporal distance with respect to the first image;
means for constructing the second image of the pair from images of the group determined.

28. A device according to claim 27, wherein the means for constructing the second image of the pair comprise means for selecting the image situated at a temporal distance that is the closest to the predetermined distance.

29. A device according to claim 27, wherein the means for constructing the second image of the pair comprise means for interpolating at least a part of the images of the group determined.

30. A device according to claim 24, wherein the calibrating means comprise means for readjustment of the signal.

31. A device according to claim 30, wherein the means for signal readjustment are means for luminance readjustment.

32. A device according to claim 24, wherein the calibrating means comprise means for geometric readjustment.

33. A device according to claim 32, wherein the means for geometric readjustment are means for vertical readjustment.

34. A device according to claim 32, wherein the means for geometric readjustment are means for rotational readjustment.

35. A device according to claim 32, wherein the means for rotational readjustment comprise:
means for defining an image part on an image to calibrate of the pair formed;
means for searching with respect to at least one block of predetermined size of the image part for a rotation with respect to a spatially-corresponding block in the other image of the pair;
means for verifying the correspondence of the rotation found with respect to at least one other part of the image to calibrate; implementation in case of positive search by the searching means;
means for correcting the image to calibrate by performing the inverse rotation to the rotation found, implemented in case of positive verification by the verification means.

36. A device according to claim 35, further comprising means for determining at least one significant block in the defined image part.

37. A device according to claim 35, wherein the means for searching for a rotation comprise:
means for defining several rotation centers and several rotation angles;
means for calculating similarity between the current block of the image to calibrate having undergone a rotation about one of the rotation centers and through one of the rotation angles, and the spatially corresponding block of the other image of the pair, implemented for all the rotation centers and for all the rotation angles:
means for comparing the similarities so calculated, the greatest similarity being that corresponding to the rotation center and the rotation angle of the rotation to be found.

38. A device according to claim 37, wherein the means for verifying the correspondence of the rotation found comprise:
means for calculating similarity between the current block of the image part to calibrate having undergone a rotation about the rotation center and through the rotation angle of the rotation found and the spatially corresponding block of the other image of the pair;
means for comparing the similarity so calculated with a threshold, the verification being positive when said similarity is greater than said threshold.

39. A device according to claim 24, wherein the means for constructing a stereoscopic signal comprise means for grouping together the pairs of images formed so as to obtain a sequence of stereoscopic images.

40. A device according to claim 24, wherein the means for constructing a stereoscopic signal comprise means for selecting a pair of images from the pairs of images formed, so as to obtain a stereoscopic image.

41. A device according to claim 40, wherein the means for selecting a pair comprise means for calculating a criterion specific to the signal such as the variance of the histogram or the mathematical correlation between the images of the pair.

42. A device according to claim 40, wherein the means for selecting a pair of images comprise a user interface making it possible to vary the angles of view of the images and/or the depth of the images.

43. A device according to claim 42, wherein it comprises means for displaying the constructed stereoscopic image and means for validation by the user.

44. A device according to claim 42, wherein the user interface makes it possible to change one of the two images of the pair or each of the two images of the pair by an image that is earlier or later with respect to the sequence of images captured.

45. An image acquisition device, comprising a device according to claim 24.

46. An information storage means which can be read by a computer or a microprocessor storing instructions of a computer program, wherein it makes it possible to implement a method of obtaining a stereoscopic signal according to claim 1.

47. A partially or totally removable information storage means which can be read by a computer or a microprocessor storing instructions of a computer program, wherein it makes it possible to implement a method of obtaining a stereoscopic signal according to claim 1.

48. A computer program product which can be loaded into a programmable apparatus, comprising sequences of instructions for implementing a method of obtaining a stereoscopic signal according to claim 1, when the program is loaded and executed by the programmable apparatus.
